(19) United States
(12) Patent Application Publication
(10) Pub. No.: US 2014/0197449 A1
(43) Pub. Date: Jul. 17, 2014

(54) SEMICONDUCTOR RECTIFIER DEVICE

(71) Applicant: Electronics and Telecommunications Research Institute, Daejeon (KR)

(72) Inventors: Kunsik PARK, Daejeon (KR); Kyoung IL NA, Daejeon (KR); JIN-GUN KOO, Daejeon (KR); Jin Ho LEE, Daejeon (KR); Jong II WON, Daejeon (KR)

(73) Assignee: Electronics and Telecommunications Research Institute, Daejeon (KR)

(21) Appl. No.: 14/155,232

(22) Filed: Jan. 14, 2014

(30) Foreign Application Priority Data
Jan. 14, 2013 (KR) 10-2013-0003888
Oct. 29, 2013 (KR) 10-2013-0129431

(51) Int. Cl. H01L 29/747

(52) U.S. Cl. CPC H01L 29/747
USPC 257/130

(57) ABSTRACT

Provided is a semiconductor rectifier device. The semiconductor rectifier device may include a substrate doped with a first conductive type, a second electrode provided on a bottom surface of the substrate, an active region and a field region defined on the substrate, a gate provided in the active region, a gate insulating film provided between the gate and the substrate, body regions provided on the substrate adjacent to first and second sides of the gate, facing each other, and doped with a second conductive type dopant different from the first conductive type, and a second conductive type plug region formed on the substrate adjacent to third and fourth sides of the gate, connecting the first and second sides.

### CROSS-REFERENCE TO RELATED APPLICATIONS

This U.S. non-provisional patent application claims priority under 35 U.S.C. §119 of Korean Patent Application Nos. 10-2013-0003888, filed on Jan. 14, 2013, and 10-2013-0129431, filed on Oct. 29, 2013, the entire contents of which are hereby incorporated by reference.

### BACKGROUND OF THE INVENTION

The present invention disclosed herein relates to a semiconductor device, and more particularly, to a semiconductor rectifier device.

High voltage high-power semiconductor rectifiers are diversely applied as power suppliers and power converters. A p-n junction diode has a little leakage current and particularly has a high reliability at a high temperature. However, due to a high forward voltage of −0.7 V and current conduction properties using a little number of carriers, p-n junction diodes have a low switching speed such as a reverse recovery time. On the contrary, Schottky diodes, since using appropriate metal electrodes, have a low forward voltage and conduction properties using a large number of carriers, thereby having a small a reverse recovery time. However, since Schottky diodes have a large leakage current at an off state and have a reliability deteriorating on a contact portion between a metal and a semiconductor at a high temperature, an additional treatment for controlling heat is necessary.

U.S. Pat. No. 5,818,084 (R. K. Williams et al.) discloses a rectifier diode configuration, in which an anode is formed by connecting a drain, a gate, and a body at the same time and using a source as a cathode in a metal oxide semiconductor field effect transistor (MOSFET) structure. In the rectifier diode described above, since having a lower turn-on voltage than general MOS connection diodes forming an anode by connecting a drain and a gate and forming a cathode by connecting a source and a body and having conduction properties using a large number of carriers, a reverse recovery time is smaller than those of p-n diodes, a leakage current is small, and a reliability at a high temperature is excellent.

On the other hand, U.S. Pat. Nos. 6,186,408, 6,331,455, 6,420,225, 6,448,160, 6,765,264, 6,979,861, etc. disclose diverse methods of manufacturing rectifiers using the MOSFET structure. The rectifiers described above commonly include a guard-ring region and an active region formed of a plug region, a tetragonal shaped gate, a body diffusion region, and a drain diffusion region.

However, in the rectifier, the gate includes a convex corner portion, in which a deterioration of breakdown voltage and uneven forward voltage properties occur due to an uneven channel length and a localized electric field. Since such phenomena become more serious in case of rectifiers having a short channel length, additional measures are necessary.

### SUMMARY OF THE INVENTION

The present invention provides a semiconductor rectifier device having low forward voltage properties, a high switching speed, and excellent leakage current properties.

Embodiments of the present invention provide rectifier devices including a substrate doped with a first conductive type, the substrate having an active region and a field region, a second electrode on a bottom surface of the substrate, a gate on the active region, a gate insulating film between the gate and the substrate, body regions in the substrate adjacent to first and second sides of the gate, facing each other, and doped with a second conductive type dopant different from the first conductive type; and a second conductive type plug region in the substrate adjacent to third and fourth sides of the gate, connecting the first and second sides.

In some embodiments, the body regions may include a first body region and a second body region on a bottom surface of the first body region.

In other embodiments, the plug region may be doped in higher impurity concentrations than the body region.

In still other embodiments, the plug region may be overlapped with the third side and fourth side of the gate.

In even other embodiments, the rectifier device may further include a first electrode electrically connecting the body regions, the plug region, and the gate.

In yet other embodiments, the rectifier device may further include a drain region in the body regions and doped with a dopant of the first conductive type.

In far other embodiments, the rectifier device may further include a first electrode electrically connecting the drain region, the plug region, and the gate.

In further embodiments, the rectifier device may further include a second conductive type guard-ring region surrounding the active region.

In still further embodiments, the guard-ring region and the plug region may be connected to each other.

In even further embodiments, the rectifier device may further include a surrounding gate on the guard-ring region.

In yet further embodiments, the rectifier device may further include a first electrode electrically connecting the guard-ring region, the surrounding gate, the gate, the plug region, and the body region.

In much further embodiments, both sides of the surrounding gate, facing each other, may be extended toward the guard-ring region.

In a lot further embodiments, the gates may be connected in the second direction and the gates and the surrounding gate are connected to one another.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1A is a top view illustrating a semiconductor rectifier device according to an embodiment of the present invention;

FIG. 1B is an enlarged view illustrating “A” shown in FIG. 1A;

FIG. 1C is a cross-sectional view illustrating an example of a part taken along a line I-I′ shown in FIG. 1B;

FIG. 1D is a cross-sectional view illustrating another example of the part taken along the line I-I′;

FIG. 1E is a cross-sectional view illustrating a part taken along a line II-II′ shown in FIG. 1B;

FIG. 2A is a top view illustrating a semiconductor rectifier device according to another embodiment of the present invention;

FIG. 2B is an enlarged view illustrating “B” shown in FIG. 2A;

FIG. 2C is a cross-sectional view illustrating a part taken along a line III-III′ shown in FIG. 2B;

FIG. 3A is a top view illustrating a semiconductor rectifier device according to still another embodiment of the present invention; and

FIG. 3B is an enlarged view illustrating “C” shown in FIG. 3A.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

Hereinafter, embodiments of the present invention will be described in detail with reference to the attached drawings.

Advantages of the embodiments compared with general technologies will be apparent through a detailed description with reference to the drawings and following claims. Particularly, the present invention will be well pointed out and clearly defined in the claims. However, the present invention will be best understood by referring to the following detailed description related to the attached drawings. Throughout the drawings, like reference numerals refer to like elements.

Hereafter, configurations of semiconductor rectifier devices according to the embodiments of the present invention will be described in detail with reference to the drawings.

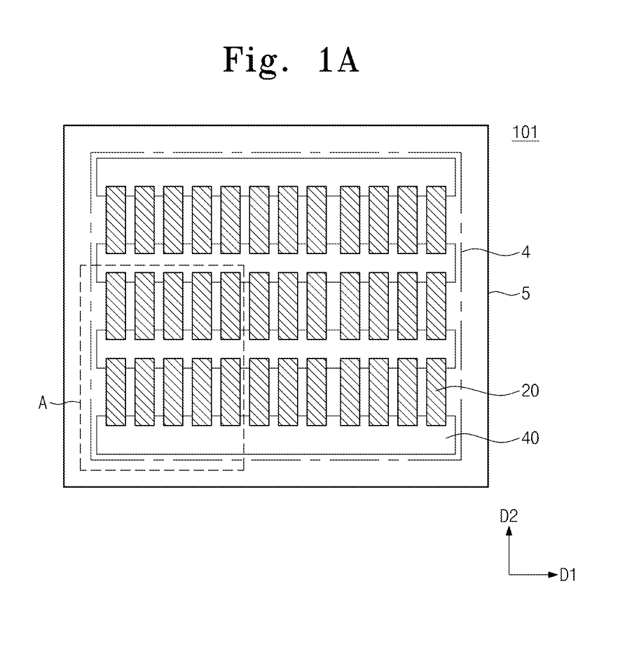

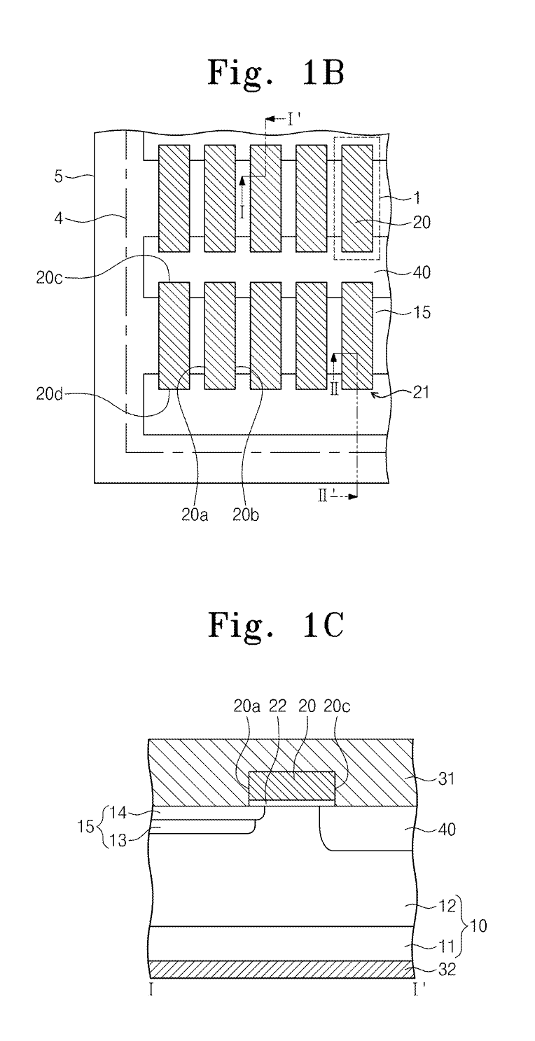

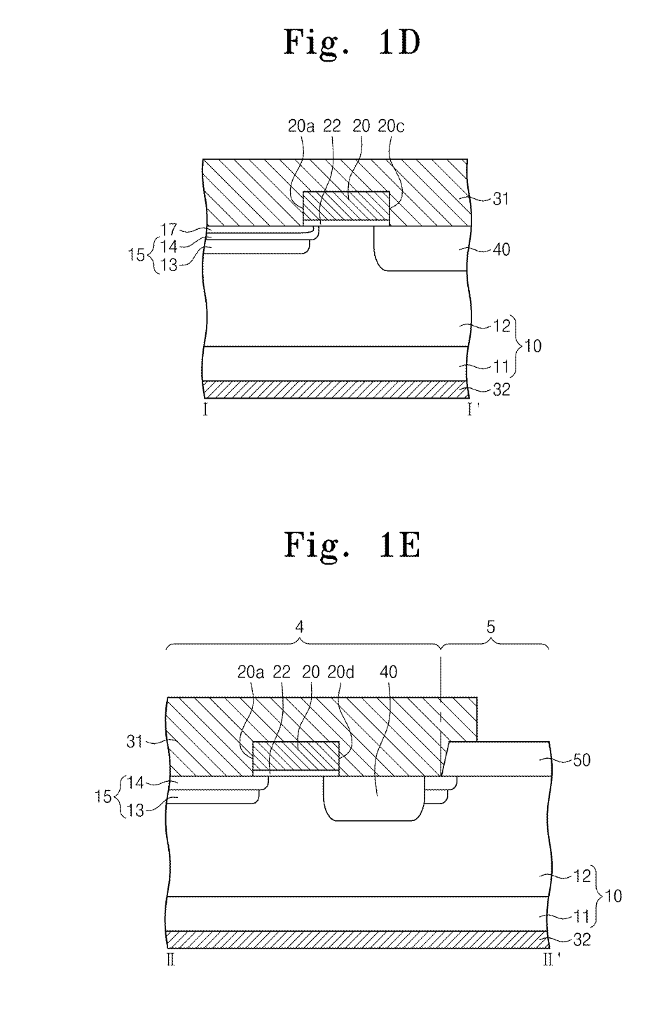

FIG. 1A is a top view illustrating a semiconductor rectifier device 101 according to an embodiment of the present invention. FIG. 1B is an enlarged view illustrating “A” shown in FIG. 1A. FIGS. 1C and 1D are cross-sectional views illustrating examples of a part taken along a line I-I′ shown in FIG. 1B. FIG. 1E is a cross-sectional view illustrating a part taken along a line II-II′ shown in FIG. 1B.

Referring to FIGS. 1A to 1E, the semiconductor rectifier device 101 may include a substrate 10, an active region 4 and a field region 5 defined on the substrate 10, a gate 20 provided in the active region 4, a gate insulating film 22 between the gate 20 and the substrate 10, body regions 15 adjacent to first and second sides 20a and 20b of the gate 20 facing each other, and a plug region 40 adjacent to third and fourth sides 20c and 20d of the gate 20 connecting the first and second sides 20a and 20b.

The substrate 10 may include a base substrate 11 and an epitaxial layer 12. The base substrate 11 may be a first conductive type, for example, an N type semiconductor substrate such as a silicon substrate. The epitaxial layer 12 may be formed by performing an epitaxial growth process on the base substrate 11. The epitaxial layer 12 may be doped in lower impurity concentrations than the base substrate 11. For example, the impurity concentrations of the epitaxial layer 12 may be from about 10¹⁴ to 10¹⁶ cm⁻³. The epitaxial layer 12 may be doped by using an in-situ method or an ion injection method. However, the substrate 10 is not limited thereto. According to other embodiments, the substrate 10 may be formed of a bulk semiconductor substrate doped with a first conductive type dopant or other shapes.

The substrate 10 may include the active region 4 doped with impurities and the field region 5 for defining the active region 4. The field region 5 may electrically segregate the active region 4. The field region 5 may be an oxide film, for example, dioxide silicon provided between the substrate 10 and a first electrode 31. However, the present embodiment is not limited thereto. In other embodiments, the oxide film of the field region 5 may further include other materials such as a silicon nitride.

The gate 20 may be disposed on the epitaxial layer 12. The gate 20 may be provided in a unit cell 1. A plurality of unit cells 1 may be arranged as a matrix in a first direction D1 and a second direction D2. The first direction D1 and the second direction D2 may be perpendicular to each other. The gate 20 is formed of a conductive material. For example, the gate 20 may be a fireproof metal, a fireproof metal silicide, or doped polycrystalline silicon. When the gate 20 is formed of polycrystal silicon, the gate 20 may be doped using an in-situ method, an ion injection method, or a gas phase doping method such as a POCl₃ doping method.

The gate insulating film 22 may be disposed between the gate 20 and the epitaxial layer 12. That is, the epitaxial layer 12 and the gate 20 may be separated by the gate insulating film 22. The gate insulating film 22 may be formed of oxide, for example, silicon dioxide. However, the present embodiment is not limited thereto. In other embodiments, the gate insulating film 22 may further include other materials, for example, silicon nitrides.

A body region 15 may be disposed in the epitaxial layer 12 adjacent to the first side 20a and second side 20b of the gate 20, facing each other. The body region 15 may be doped with a second conductive type dopant differing from the first conductive type. The body region 15 may include a first body region 13 and a second body region 14. The body region 15 may be formed by injecting second conductive type dopant ions by using the gate 20 as a mask. The first body region 13 may be disposed below the second body region 14. A dopant for forming the second body region 14 may be heavier than a dopant for forming the first body region 13. For example, when the second conductive type is P type, the dopant for forming the second body region 14 may be BF₂ and the dopant for forming the first body region 13 may be boron. The body region 15 may be overlapped with the first side 20a and second side 20b of the gate 20. The first body region 13 may be more extended below the gate 20 than the second body region 14.

The plug region 40 may be disposed in the epitaxial layer 12 adjacent to the third side 20c and fourth side 20d of the gate 20, connecting the first and second sides 20a and 20b facing each other. The plug region 40 may be overlapped with the third side 20c and fourth side 20d of the gate 20. The plug region 40 may be doped with the second conductive type dopant. The plug region 40 may be doped in higher impurity concentrations than the body region 15. The plug region 40 may have a depth of from about 1 μm to about 10 μm. Since a turn-on voltage below edges of the gate 20, that is, the third and fourth sides 20c and 20d is higher than a turn-on voltage below edges of the gate 20 above the body region 15, that is, the first and second sides 20a and 20b due to the plug region 40, the edges of the gate 20 may not be used as a path of current. In result, the semiconductor rectifier device 101 may be improved in uniformity of forward turn-on properties and reverse pressure-resistant properties.

A drain region 17 may be disposed on the body region 15. The body region 17 may be disposed in the second body region 14 adjacent to the first side 20a and second side 20b of the gate 20, facing each other. The drain region 17 may be formed by injecting the first conductive type dopant into the body region 15 using the gate 20 as a mask. After injecting the first conductive type dopant, the dopant in the drain region 17 may be activated or diffused by performing a heat treatment process. The body region 17 may be overlapped with the first side 20a and second side 20b of the gate 20. Concentrations of the first conductive type dopant in the drain region 17 may be higher than the concentrations of the second conductive type dopant in the body region 15. The concentrations of the first conductive type dopant in the drain region 17 may be lower than the concentrations of the second conductive type dopant in the plug region 40.

The first electrode 31 may be disposed above the epitaxial layer 12. The first electrode 31 may be electrically connected to the drain region 17, the body region 15, the plug region 40, and the gate 20. The first electrode 31 may include at least one of a metal, a conductive metal nitride, and a metal-semiconductor compound.

A second electrode 32 may be disposed below the substrate 10. The second electrode 32 may be electrically connected to a bottom surface of the base substrate 11. The second electrode 32 may be formed of same material as that of the first electrode 31. For example, the second electrode 32 may include at least one of a metal, a conductive metal nitride, and a metal-semiconductor compound.

One of the first conductive type and the second conductive type is N type and another is P type. When the first conductive type is the N type and the second conductive type is the P type, a transistor structure may be an N-channel metal oxide semiconductor (NMOS) transistor structure and the first electrode 31 may be a positive electrode and the second electrode 32 may be a negative electrode. Differently, when the first conductive type is the P type and the second conductive type is the N type, the transistor structure may be a P-channel metal oxide semiconductor (PMOS) transistor and the first electrode 31 may be a negative electrode and the second electrode may be a positive electrode. For example, when the first conductive type is the N type and the second conductive type is the P type, a forward current may flow from the first electrode 31 to the second electrode 32. Differently, when the first conductive type is the P type and the second conductive type is the N type, a forward current may flow from the second electrode 32 to the first electrode 31.

When a forward voltage is applied to the first and second electrodes 31 and 32 of the semiconductor rectifier device 101, the second body region 14 of the transistor structure is turned on. According thereto, a forward turn-on voltage of the semiconductor rectifier device 101 may be decreased. Also, since using a plurality of carriers having a transistor structure, the semiconductor rectifier device 101 has a short reverse restoration time. In result, the semiconductor rectifier device may have a fast switching speed, a low leakage current, and excellent reliability at a high temperature.

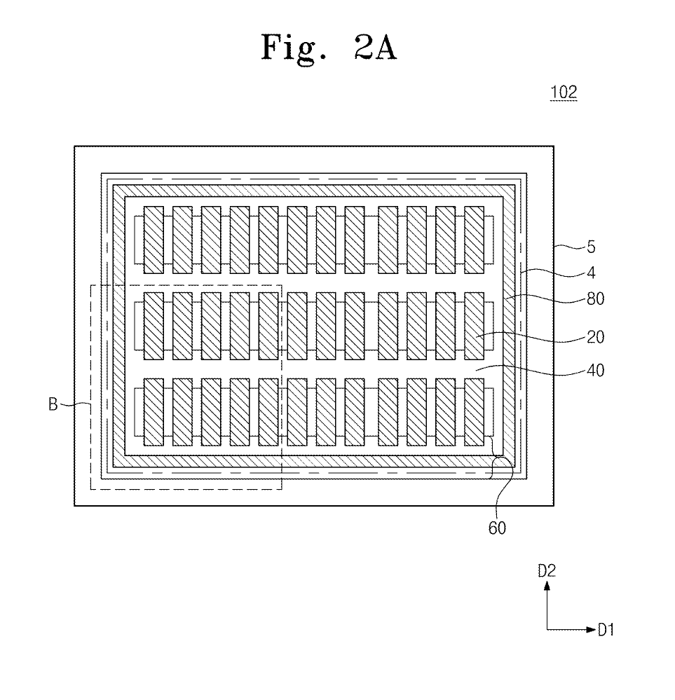

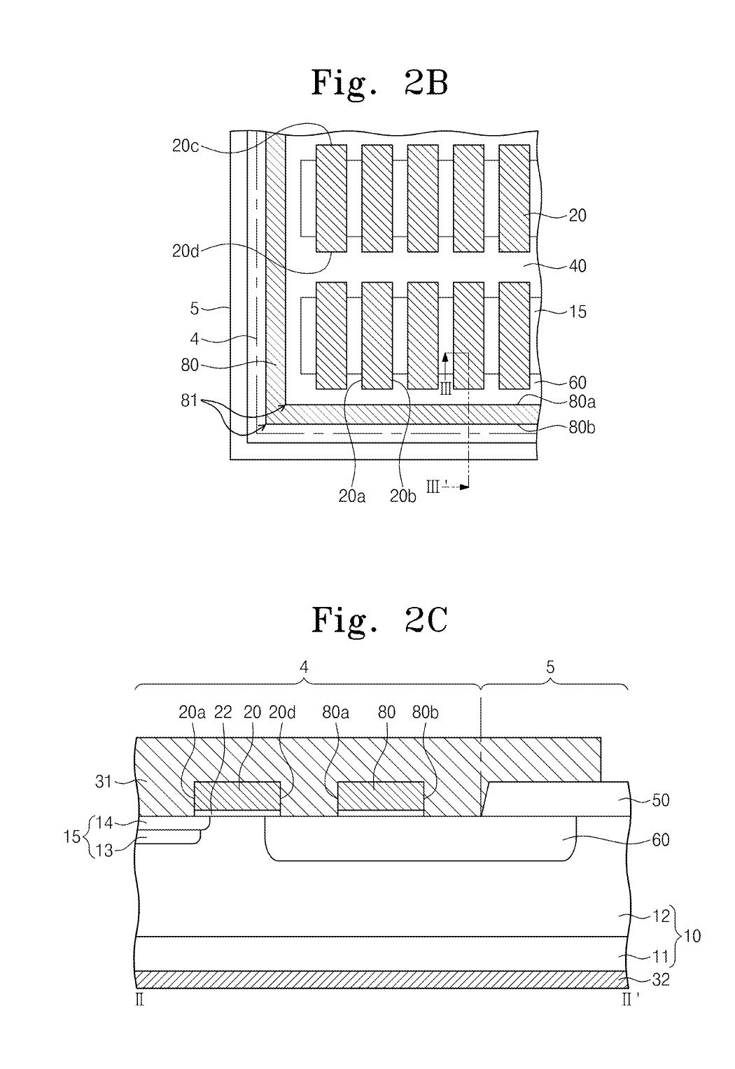

FIG. 2A is a top view illustrating a semiconductor rectifier device 102 according to another embodiment of the present invention. FIG. 2B is an enlarged view illustrating “B” shown in FIG. 2A. FIG. 2C is a cross-sectional view illustrating a part taken along a line III-III′ shown in FIG. 2B. Like reference numerals refer to like elements described above. For convenience of description, descriptions for the same elements will be omitted or briefly described. That is, differences between the described embodiment and modifications will be described.

Referring to FIGS. 2A to 2C, the semiconductor rectifier device 102 may include the substrate 10 including the active region 4, a plurality of gates 20 provided as a matrix in the first and second directions D1 and D2, the body regions 15 between the first and second sides of the gates 20, facing each other, the plug region 40 extended in the first direction D1 between the third and fourth sides of the gates 20, and a guard-ring region 60 surrounding the active region 4.

A surrounding gate 80 may be additionally further disposed on the guard-ring region 60. The guard-ring region 60 may be disposed in the epitaxial layer 12 adjacent to sidewalls 80a and 80b of the surrounding gate 80, facing each other. The guard-ring are 60 may be overlapped with the sidewalls 80a and 80b of the surrounding gate 80. The guard-ring region 60 may be doped with same conductive type as the plug region 40. The guard-ring region 60 may be formed by injecting a second conductive type dopant different from a first conductive type and performing a heat treatment thereon. The guard-ring region 60 may have a depth of from about 1 μm to about 10 μm. The guard-ring region 60 and the plug region 40 may be connected to each other. The guard-ring region 60 may be doped with higher impurity concentrations than the body region 15. A corner 81 of the surrounding gate 80 may not be used as a path of current due to the guard-ring region 60. In result, the semiconductor rectifier device may be improved in uniformity of forward direction turn-on properties and reverse pressure-resistant properties.

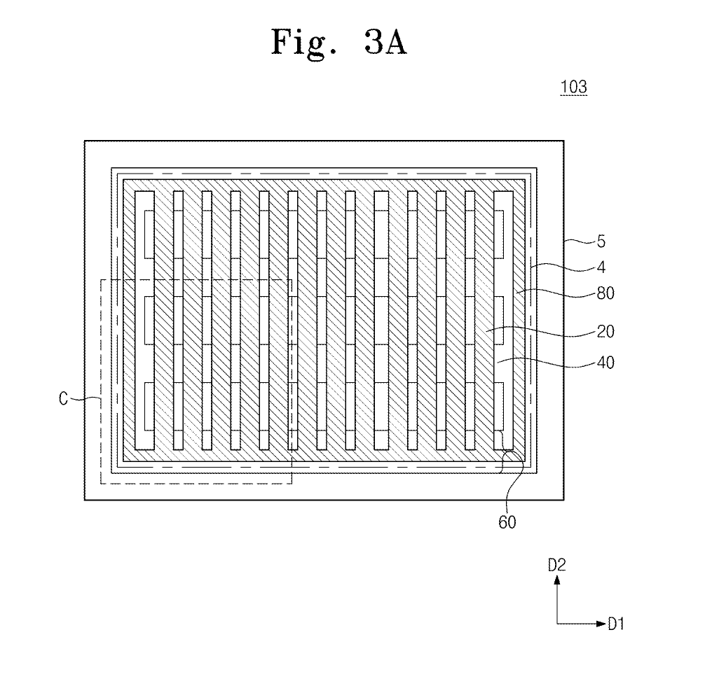

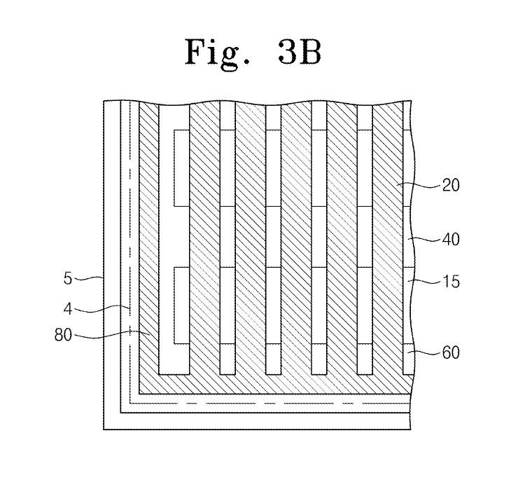

FIG. 3A is a top view illustrating a semiconductor rectifier device 103 according to still another embodiment of the present invention. FIG. 3B is an enlarged view illustrating “C” shown in FIG. 3A. Like reference numerals refer to like elements described above. For convenience of description, descriptions for the same elements will be omitted or briefly described. That is, differences between the described embodiment and modifications will be described.

Referring to FIGS. 3A and 3B, in the semiconductor rectifier device 104, the gates 20 may be connected in the second direction D2 and the gates 20 and the surrounding gate 80 may also be connected in the second direction D2.

In the semiconductor rectifier device according to the embodiment, a plug region or a guard-ring region is formed below an edge of a gate deteriorating device properties not to form a channel. As a result thereof, the device may increase uniformity of forward turn-on properties and pressure-resistant properties in a reverse direction.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A rectifier device comprising:
a substrate doped with a first conductive type, the substrate having an active region and a field region;
a second electrode on a bottom surface of the substrate;
a gate on the active region;
a gate insulating film between the gate and the substrate;
body regions in the substrate adjacent to first and second sides of the gate, facing each other, the body regions doped with a second conductive type dopant different from the first conductive type; and
a second conductive type plug region in the substrate adjacent to third and fourth sides of the gate, connecting the first and second sides.

2. The rectifier device of claim 1, wherein the body regions comprise a first body region and a second body region on a bottom surface of the first body region.

3. The rectifier device of claim 1, wherein the plug region is doped in higher impurity concentrations than the body region.

4. The rectifier device of claim 1, wherein the plug region is overlapped with the third side and fourth side of the gate.

5. The rectifier device of claim 1, further comprising a first electrode electrically connecting the body regions, the plug region, and the gate.

6. The rectifier device of claim 1, further comprising a drain region provided in the body regions and doped with a dopant of the first conductive type.

7. The rectifier device of claim 6, further comprising a first electrode electrically connecting the drain region, the plug region, and the gate.

8. The rectifier device of claim 1, further comprising a second conductive type guard-ring region surrounding the active region.

9. The rectifier device of claim 8, wherein the guard-ring region and the plug region are connected to each other.

10. The rectifier device of claim 8, further comprising a surrounding gate on the guard-ring region.

11. The rectifier device of claim 10, further comprising a first electrode electrically connecting the guard-ring region, the surrounding gate, the gate, the plug region, and the body region.

12. The rectifier device of claim 10, wherein both sides of the surrounding gate, facing each other, are extended toward the guard-ring region.

13. The rectifier device of claim 10, wherein the gates are connected in the second direction and the gates and the surrounding gate are connected to one another.
